(19) United States
(12) Patent Application Publication
(10) Pub. No.: US 2012/0263978 A1
(43) Pub. Date: Oct. 18, 2012

(54) ENERGY STORAGE DEVICE AND METHOD OF MANUFACTURING THE SAME

(76) Inventors: Chung-Hsiung Wang, Hsinchu City (TW); Chi-Feng Lin, Hsinchu County (TW); Han-Yang Chung, Taoyuan County (TW); Wen-Hsiung Liao, Hsinchu County (TW)

(21) Appl. No.: 13/445,856

(22) Filed: Apr. 12, 2012

Related U.S. Application Data
(60) Provisional application No. 61/475,237, filed on Apr. 14, 2011.

(30) Foreign Application Priority Data
Apr. 6, 2012 (TW) 101112250

(51) Int. Cl. H01M 2/00; H05K 5/00; H01M 10/04

(52) U.S. Cl. 429/7; 29/623.2; 29/25.41; 174/520

(57) ABSTRACT

An energy storage device and a method of manufacturing the same are disclosed. The energy storage device includes a circuit board, a conductive cover disposed above the circuit board, a sealing structure, a metal coating layer, and an electrochemical cell. The sealing structure is disposed between the circuit board and the circumference of the conductive cover such that the circuit board, the conductive cover, and the sealing structure together form a sealed space where the electrochemical cell is disposed. The metal coating layer continuously covers a part of the conductive cover, an exposed portion of the sealing structure, and a part of the circuit board. Therefore, even if the energy storage device needs to be heated during a product assembly, the metal coating layer can keep the sealing structure structurally stable, and the electrolyte of the electrochemical cell will not leak; the whole energy storage device therefore can keeps undamaged.

### CROSS REFERENCE TO RELATED APPLICATIONS

This application claims the benefit of U.S. Provisional Application No. 61/475,237, which was filed on Apr. 14, 2011 and is incorporated herein by reference.

### BACKGROUND OF THE INVENTION

1. Field of the Invention

The invention relates to an energy storage device and a method of manufacturing the same, and especially relates to an energy storage device of electrochemical cell and a method of manufacturing the same.

2. Description of the Prior Art

The demand of portable electronic products (such as hand phone, tablet computer and so on) to energy storage device (such as secondary battery or electric double-layer capacitor) is not merely for being high energy density and light weight. As the size and the production difficulty of electronic products are required to be reduced, the above demand is also for being small-sized and being capable of being welded on a printed circuit board by surface mount technique (SMT) so as to increase the utilization of the surface of the printed circuit board.

Conventional small energy storage devices are substantially categorized into a coin type and a chip type of surface mount design (SMD). The energy storage devices of the coin type as a whole are provided in a short column. The upper cover and the bottom cover thereof are clamped with each other to form an accommodating space. A gasket is also clamped therebetween for insulation. The gasket is also taken as an inner insulation structure in the accommodating space. The terminals for the positive and negative electrodes are welded on the upper cover and the bottom cover respectively and extend outward to the same plane.

Conventional energy storage device of the chip type are sealed by press fitting. Some electrolyte may leak due to compression induced in a press fitting process. Besides, if the force of the press fitting is unstable or the disposition of the gasket is incorrect, the gasket tends to be cracked during the press fitting process, leading to a short of the positive and negative electrodes. Furthermore, the energy storage device of the coin type is easily deformed by a heat impact during product assembly, so that a crack occurs between the upper cover and the bottom cover leading to leakage of the electrolyte along the crack. In addition, because the energy storage devices of the coin type are sealed by press fitting, the layout area therefor is difficult to be reduced. Besides, the terminals extend outward, so the area utilization by the energy storage device is so low that the disposition density of devices on the printed circuit board is poor.

Conventional energy storage devices of the chip type of SMD form an accommodating space by jointing and sealing a concave receptacle with a plate part. The contact area of the concave receptacle and the plate part is usually small, leading to insufficient welding strength and sealability. If an insulation receptacle is taken as the concave receptacle is insulated, the positive and negative electrodes of the energy storage device are usually integrated into the production of the insulation receptacle. The difficulty of the production is high. The yield rate of the production is hardly improved. Not only may the heat for jointing the concave receptacle and the plate part in a metal welding way influence the electrolyte properties and the circuit structure stability, but also the welded structure may be softened or fail due to being subjected to a heat impact in a product assembly of the energy storage device, leading to leakage of the electrolyte, a short of the electrodes and so on. If the concave receptacle and the plate part are jointed and sealed by a conductive adhesive, the gas tightness therefor is usually poor because the conductive adhesive is usually a mixture of resin and conductive particles.

### SUMMARY OF THE INVENTION

An objective of the invention is to provide an energy storage device, which has a metal coating layer capable of keeping a sealing structure of the energy storage device stable so as to prevent an electrolyte inside from leaking and to enhance the capability of the whole energy storage device to resist heat impact.

The energy storage device of the invention includes a circuit board, a conductive cover, a sealing structure, a metal coating layer, and an electrochemical cell. The circuit board includes an insulation substrate and a first electrode circuit and a second electrode circuit formed on the insulation substrate. The conductive cover has a circumference. The sealing structure is disposed between the circuit board and the circumference of the conductive cover such that the circuit board, the conductive cover, and the sealing structure together form a sealed space. The metal coating layer successively covers a portion of the conductive cover, an exposed portion of the sealing structure, and a portion of the circuit board. The electrochemical cell is disposed in the sealed space and electrically connected to the first electrode circuit and the second electrode circuit respectively. Thereby, even if the energy storage device needs to be heated again during a product assembly, the metal coating layer can keep the sealing structure structurally stable to maintain the sealability thereof, so the electrolyte of the electrochemical cell can be prevented from leaking so that the whole energy storage device can still function normally.

Another objective of the invention is to provide a method of manufacturing an energy storage device of the invention. The method is to prepare a circuit board, which includes an insulation substrate and a first electrode circuit and a second electrode circuit formed on the insulation substrate, and to prepare a conductive cover having a circumference. The method is also to dispose cell contents and to implement a sealing process to put and fix the conductive cover above the circuit board and to form a sealing structure between the circuit board and the circumference of the conductive cover, such that the circuit board, the conductive cover, and the sealing structure together form a sealed space, and the cell contents form an electrochemical cell in the sealed space. Therein, the electrochemical cell is electrically connected to the first electrode circuit and the second electrode circuit respectively. The method is then to form a metal coating layer successively covering a portion of the conductive cover, an exposed portion of the sealing structure, and a portion of the circuit board. At this moment, the energy storage device of the invention is substantially completed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional view of an energy storage device of an embodiment according to the invention.

FIG. 2 is a sectional view of an energy storage device of another embodiment according to the invention.

FIG. 3 is a sectional view of an energy storage device of another embodiment according to the invention.

FIG. 4 is a sectional view of an energy storage device of another embodiment according to the invention.

FIG. 5 is a sectional view of an energy storage device of another embodiment according to the invention.

FIG. 6 is a flow chart of a method of manufacturing an energy storage device of an embodiment according to the invention.

FIGS. 7 through 9 are schematic diagrams illustrating manufacturing flow of the energy storage device in FIG. 1 according to the flow chart in FIG. 6.

FIG. 10 is a flow chart of a sealing process for the energy storage device in FIG. 1 according to the flow chart in FIG. 6.

FIG. 11 is a flow chart of a sealing process for the energy storage device in FIG. 3 according to the flow chart in FIG. 6.

FIG. 12 is a schematic diagram illustrating the spreading of an adherence layer in FIG. 11.

FIG. 13 is a schematic diagram illustrating a sealing process for the energy storage device in FIG. 5 according to the flow chart in FIG. 6.

FIG. 14 is a flow chart of the sealing process for the energy storage device in FIG. 5 according to the flow chart in FIG. 6.

### DETAILED DESCRIPTION

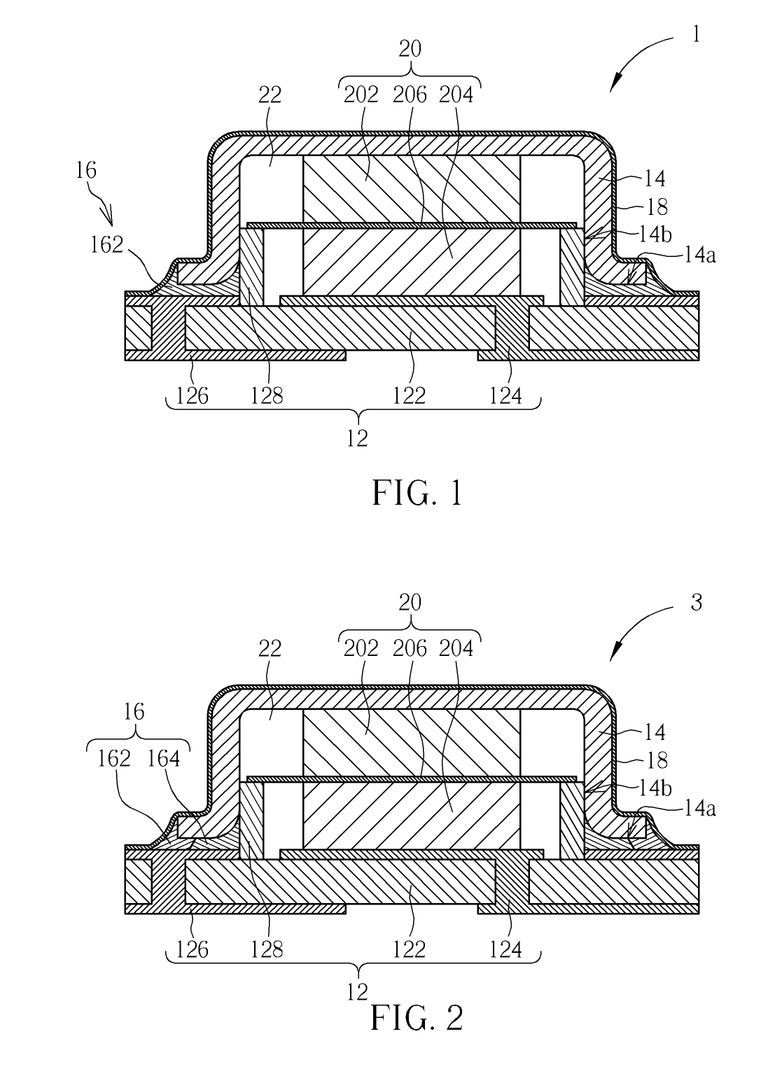

Please refer to FIG. 1, which is a sectional view of an energy storage device 1 of an embodiment according to the invention. The top-view profile of the energy storage device 1 can be a rectangle or other closed shape profile, which will not be described hereafter. In the embodiment, the energy storage device 1 includes a circuit board 12, a conductive cover 14, a sealing structure 16, a metal coating layer 18, and an electrochemical cell 20. The conductive cover 14 is disposed on the circuit board 12 and sealed by the sealing structure 16. The electrochemical cell 20 is disposed therein. The metal coating layer 18 covers the conductive cover 14, the sealing structure 16, and the circuit board 12 for structurally stabilizing the sealing structure 16. Therefore, even if the energy storage device 1 needs to be heated, the energy storage device 1 still can be maintained in structural integrity, stability, and sealability and can function normally.

For further details, in the embodiment, the circuit board 12 includes an insulation substrate 122, a first electrode circuit 124 and a second electrode circuit 126 formed on the insulation substrate 122, and an insulation protrusion ring 128 disposed on the insulation substrate 122. The insulation substrate 122 can be formed together with the insulation protrusion ring 128 in one-piece. The material therefor can be low-temperature co-fired ceramics (LTCC), high-temperature co-fired ceramics (HTCC), or synthetic resin. When co-fired ceramics is used, the forming of the first electrode circuit 124 and the second electrode circuit 126 can also be integrated into the production of the insulation substrate 122. Furthermore, the insulation protrusion ring 128 can be a laminated structure of dry films, formed on the insulation substrate 122 of alumina ceramics by a dry film process. In addition, in practice, a common printed circuit board (PCB) is applicable to realize the insulation substrate 122, the first electrode circuit 124, and the second electrode circuit 126 simultaneously. In this case, the insulation protrusion ring 128 can be disposed on the PCB separately.

The conductive cover 14 has a circumference 14a. In the embodiment, the conductive cover 14 is provided in a cup structure. The circumference 14a is located at the cup rim of the cup structure. The conductive cover 14 is disposed above the circuit board 12. The sealing structure 16 is disposed between the circuit board 12 and the circumference 14a of the conductive cover 14, so the conductive cover 14 is fixedly connected by the cup rim to the circuit board 12 through the sealing structure 16, such that the circuit board 12, the conductive cover 14, and the sealing structure 16 together form a sealed space 22. The insulation protrusion ring 128 is therefore disposed in the sealed space 22. The insulation protrusion ring 128 contacts the inner sidewall 14b of the cup structure, which is conducive to the positioning of the conductive cover 14 during the disposition of the conductive cover 14; however, the invention is not limited thereto. For example, the insulation protrusion ring 128 and the conductive cover 14 can be disposed separately. The sealing structure 16 is realized by a welding metal portion 162 and is provided in a ring structure substantially matching the top-view profile of the energy storage device 1. The metal coating layer 18 successively covers the conductive cover 14, the exposed portion of the sealing structure 16, and the circuit board 12. In the embodiment, the metal coating layer 18 covers the conductive cover 14 completely, but the invention is not limited thereto. In principle, as long as the exposed portion of the sealing structure 16 and the portions of the circuit board 12 and the conductive cover 14 adjacent to the exposed portion are successively covered, the effect of constraining the sealing structure 16 can be realized effectively.

In general, compared with macromolecule materials, metal has relatively-good sealability, so the energy storage device 1 can obtain good sealability. Furthermore, the insulation protrusion ring 128 closely contacts the inner sidewall 14b of the conductive cover 14, which is also conducive to the constraint on the sealing structure 16, so that even if the sealing structure 16 shows some fluidity when the energy storage device 1 stands heat impact, the sealing structure 16 still can be constrained effectively by the metal coating layer 18 and the insulation protrusion ring 128 so as to maintain the sealability of the energy storage device 1. In practice, the welding metal portion 162 is melted directly onto the conductive cover 14 and the metal portion of the circuit board 12, usually the second electrode circuit 126, so it would be better that the welding metal portion 162 is made of the material having good weldability to the material on the surfaces of the conductive cover 14 and the second electrode circuit 126. In a common case, the welding metal portion 162 can be made of Sn alloy. In the embodiment, the welding metal portion 162 is of Sn—Ag—Cu alloy; the metal coating layer 18 is of Cu. In this case, the copper concentration of the Sn—Ag—Cu alloy within the interface zone of the welding metal portion 162 and the metal coating layer 18 is increased by the diffusion effect of the copper atoms from the metal coating layer 18. Accordingly, the melting point of the Sn—Ag—Cu alloy here increases. It is conducive to the improvement in the structural stability of the sealing structure 16 when the energy storage device 1 suffers heat impacts. In practice, the metal coating layer 18 can be made of Ni. In this case, the metal coating layer 18 in principle provides isolation and protection for the sealing structure 16. In addition, in practice, the welding metal portion 162 can be chosen to be of a lower welding temperature, so as to reduce the influence on other components such as the electrochemical cell 20. In general, the heat impacts the energy storage device 1 suffers usually come from a reflow process during a product assembly, so the lower welding temperature can be considered to be lower than the reflow temperature (or the highest temperature of the reflow temperature profile) for the energy storage device 1, e.g. 260 degrees Celsius.

The electrochemical cell 20 is disposed in the sealed space 22 and at the inner side of the insulation protrusion ring 128 and electrically connected to the first electrode circuit 124 and the second electrode circuit 126 of the circuit board 12 respectively. In the embodiment, the electrochemical cell 20 is an electric double layer capacitor and includes an upper electrode 202, a lower electrode 204, and a separator 206. The upper electrode 202 and the lower electrode 204 can be made of active material and conductive powder. The active material can be high specific surface area carbon, carbon nanotube, grapheme, metallic oxide (e.g. ruthenium oxide), lithium oxide and so on. The conductive powder can be carbon black, graphite, grapheme and so on. The upper electrode 202 and the lower electrode 204 are porous; the electrolyte (not labeled in the figures) is accommodated therein. The solvent of the electrolyte can be carbonic acid esters (such as propylene carbonate and butylenes carbonate), lactones (such as β-butyrolactone and y-butyrolactone), sulfolanes, amide-based solvents (such as dimethylformamide), nitromethane, 1,2-dimethoxyethane, acetonitriles and so on. The salt of the electrolyte can be fluorine-containing acids (such as boric tetrafluoride, phosphoric hexafluoride, arsenic hexafluoride, antimonic hexafluoride, and fluoroalkylsulfonic acid), chlorine-containing acids (such as perchloric acid and aluminic tetrachloride), alkali metal salts-sodium salts (such as sodium salts, potassium salts and the like), alkaline earth metal salts (such as magnesium salts, calcium salts and the like), tetraalkylphosphonium salts (such as tetramethylphosphonium salts, tetraethylphosphonium slats and the like). The separator 206 can be one of hydrophilic porous films (such as Polytetrafluoroethylene, polyethylene, polypropylene, polyimide, and polyimide-amide, glass fiber, porous sheets obtained from sisal, and cellulose). The lower electrode 204 is disposed on the circuit board 12 and electrically connected to the first electrode circuit 124; a conductive adhesive can be coated therebetween. The upper electrode 202 is disposed above the lower electrode 204 and electrically connected to the second electrode circuit 126 by the conductive cover 14; a conductive adhesive can be coated between the upper electrode 202 and the conductive cover 14. The separator 206 is disposed between the upper electrode 202 and the lower electrode 204. In the embodiment, the separator 206 is also disposed on the insulation protrusion ring 128. The insulation protrusion ring 128 functions as a separator for electrically separating the lower electrode 204 and the conductive cover 14, which can also prevent any short between the upper electrode 202 and the lower electrode 204.

Therefore, in the energy storage device 1 according to the invention, the conductive cover 14 and the circuit board 12 are connected by adhesion, so as to avoid the problem induced by the press fitting method for sealing the energy storage device of the coin type in the prior art. Furthermore, the energy storage device 1 can use the metal coating layer 18 to keep the sealing structure 16 structurally stable so as to prevent the sealability of the energy storage device 1 from being damaged when suffering heat impact and to avoid leakage of the electrolyte of the electrochemical cell 20, so that the whole energy storage device 1 can still function normally. It solves the problem in the prior art that the sealability of the smaller energy storage devices is hardly maintained when the smaller energy storage devices suffer a heat impact. In addition, although the embodiment is illustrated by an electric double-layer capacitor, the invention is not limited thereto.

In the above embodiment, the sealing structure 16 of the energy storage device 1 uses only the welding metal portion 162 of single structure, but the invention is not limited thereto. Please refer to FIG. 1 and FIG. 2. FIG. 2 is a sectional view of an energy storage device 3 of another embodiment according to the invention. The energy storage device 3 is substantially equal to the energy storage device 1 in structure. The most components of the energy storage device 3 continue use the labels used for the energy storage device 1. The main difference is that the sealing structure 16 of the energy storage device 3 further includes an adhesive portion 164 disposed between the circuit board 12 and the circumference 14a of the conductive cover 14. Both the welding metal portion 162 and the adhesive portion 164 are provided in ring structures. The adhesive portion 164 is disposed at the inner side of the welding metal portion 162. In practice, the adhesive portion 164 can be made of macromolecule material such as polyphenylene sulfide, polyethylene terephthalate (PET), polyamide, polyimide, polyether ether ketone, liquid crystal polymer (LCP), epoxy resin, silicone-based adhesive, a mixture of at least two of the above macromolecule materials, or other macromolecule material having adhesion effect; however, the invention is not limited thereto. In the embodiment, the adhesive portion 164 is cured for adhesion and sealing. For the description of the other components of the energy storage device 3, please refer to the relative description of the energy storage device 1, which is not described herein.

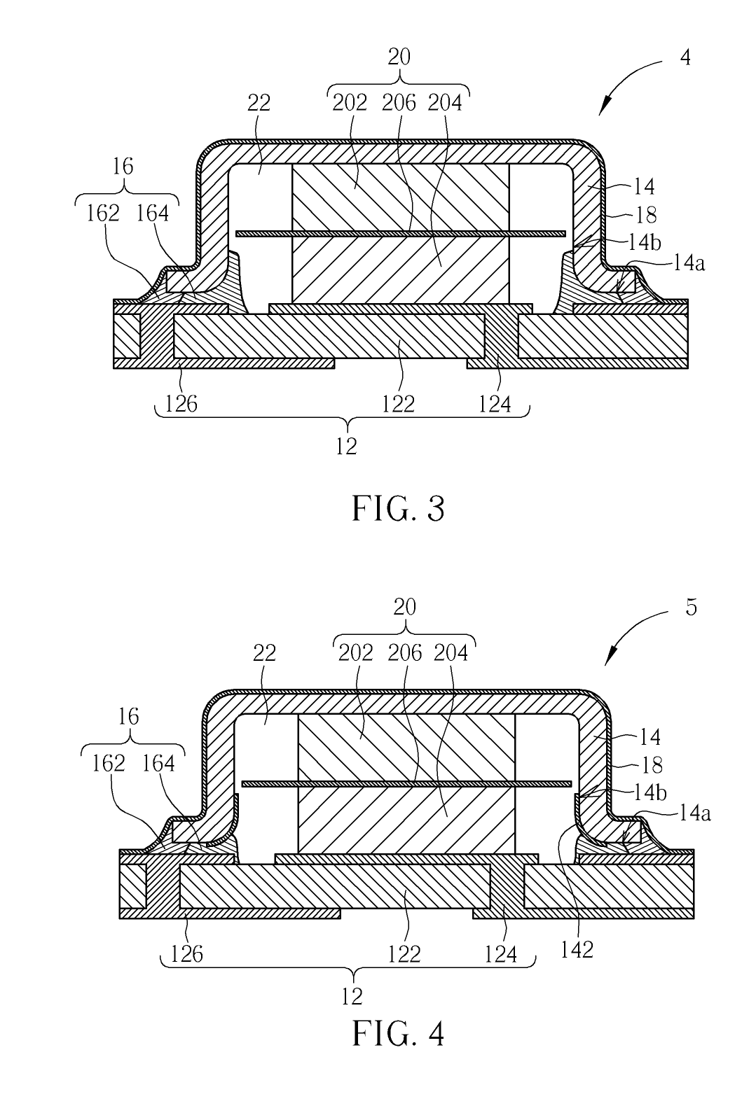

Please refer to FIG. 2 and FIG. 3. FIG. 3 is a sectional view of an energy storage device 4 of another embodiment according to the invention. The energy storage device 4 is substantially equal to the energy storage device 3 in structure. The most components of the energy storage device 4 continue use the labels used for the energy storage device 3. The main difference is that the energy storage device 4 is provided without the insulation protrusion ring 128, but the adhesive portion 164 of the sealing structure 16 of the energy storage device 4 extends upward along the inner sidewall 14b of the conductive cover 14 for electrically separating the lower electrode 204 and the conductive cover 14, so the extending-upward adhesive portion 164 also has the insulation effect as the insulation protrusion ring 128. For the description of the other components of the energy storage device 4, please refer to the relative description of the energy storage device 3, which is not described herein.

Please refer FIG. 3 and FIG. 4. FIG. 4 is a sectional view of an energy storage device 5 of another embodiment according to the invention. The energy storage device 5 is substantially equal to the energy storage device 4 in structure. The most components of the energy storage device 5 continue use the labels used for the energy storage device 4. The main difference is that the adhesive portion 164 of the sealing structure 16 of the energy storage device 5 is required to only provide adhesion effect and insulation effect for the welding metal portion 162 and the lower electrode 204. The conductive cover 14 includes an insulation coating layer 142 on its inner sidewall 14b close to the cup rim (i.e. the circumference 14a) for electrically separating the lower electrode 204 and the conductive cover 14. For the description of the other components of the energy storage device 5, please refer to the relative description of the energy storage device 4, which is not described herein.

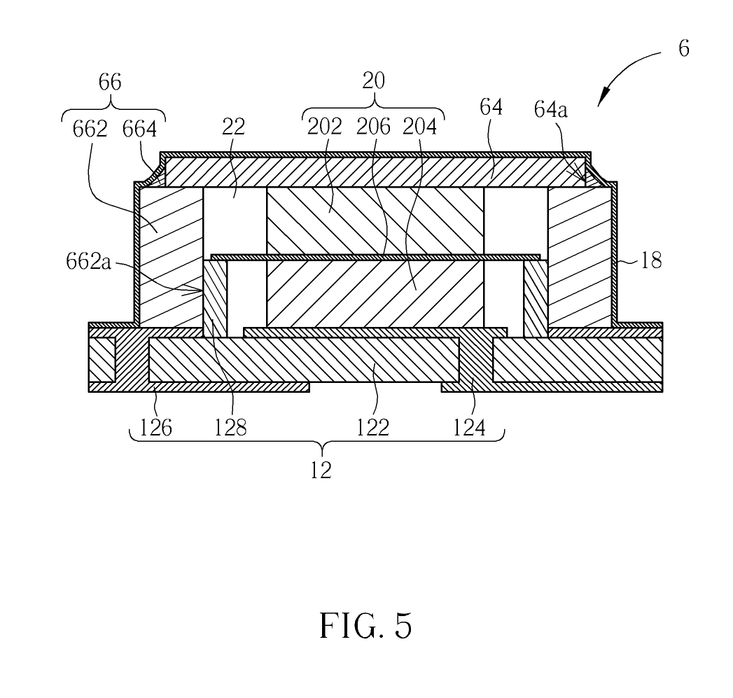

The above embodiments are based on the conductive cover 14 of cup structure, but the invention is not limited thereto. Please refer to FIG. 1 and FIG. 5. FIG. 5 is a sectional view of an energy storage device 6 of another embodiment according to the invention. The energy storage device 6 is substantially equal to the energy storage device 1 in structure. The most components of the energy storage device 4 continue use the labels used for the energy storage device 1. A conductive cover 64 of the energy storage device 6 is provided in a plate structure, but the invention is not limited thereto. A sealing structure 66 of the energy storage device 6 includes a metal support ring 662 and a welding metal portion 664. The metal support ring 662 is fixedly disposed on the circuit board 12. The insulation protrusion ring 128 contacts the inner sidewall 662a of the metal support ring 662. The conductive cover 64 is disposed on the metal support ring 662. The welding metal portion 664 seals the conductive cover 64 and the metal support ring 662. Therein, the insulation protrusion ring 128 and the metal support ring 662 are not limited to close contact; the insulation protrusion ring 128 and the metal support ring 662 can be disposed separately. For the choice for the welding metal portion 664, please refer to the relative description of the welding metal portion 162 of the energy storage device 1, but the invention is not limited thereto. For the description of the other components of the energy storage device 6, please refer to the relative description of the energy storage device 1, which is not described herein.

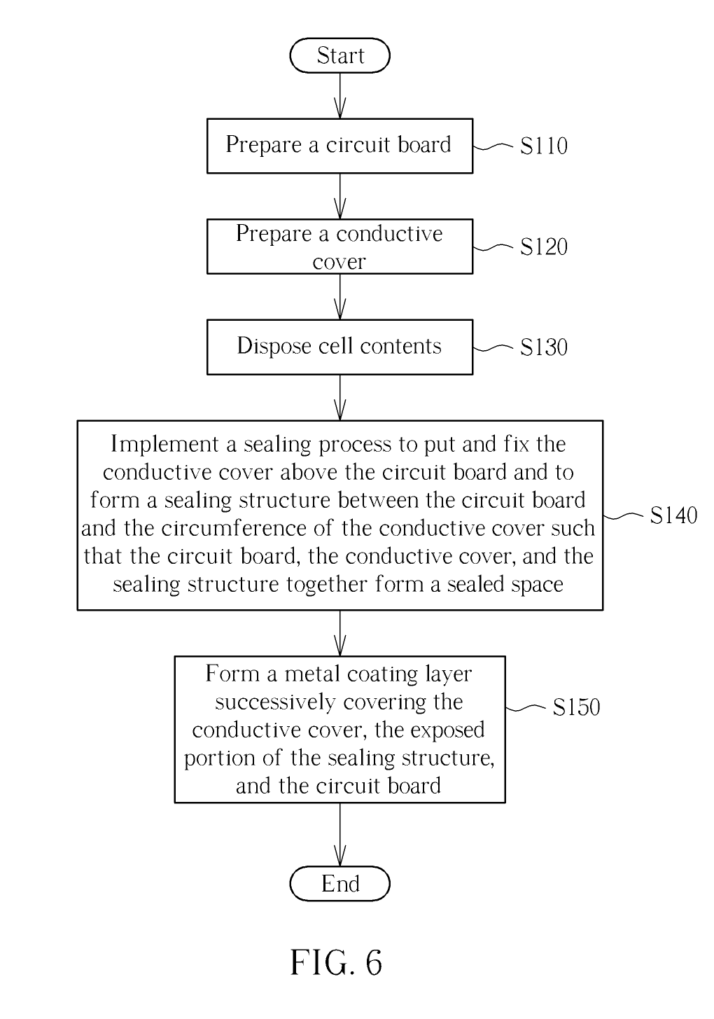

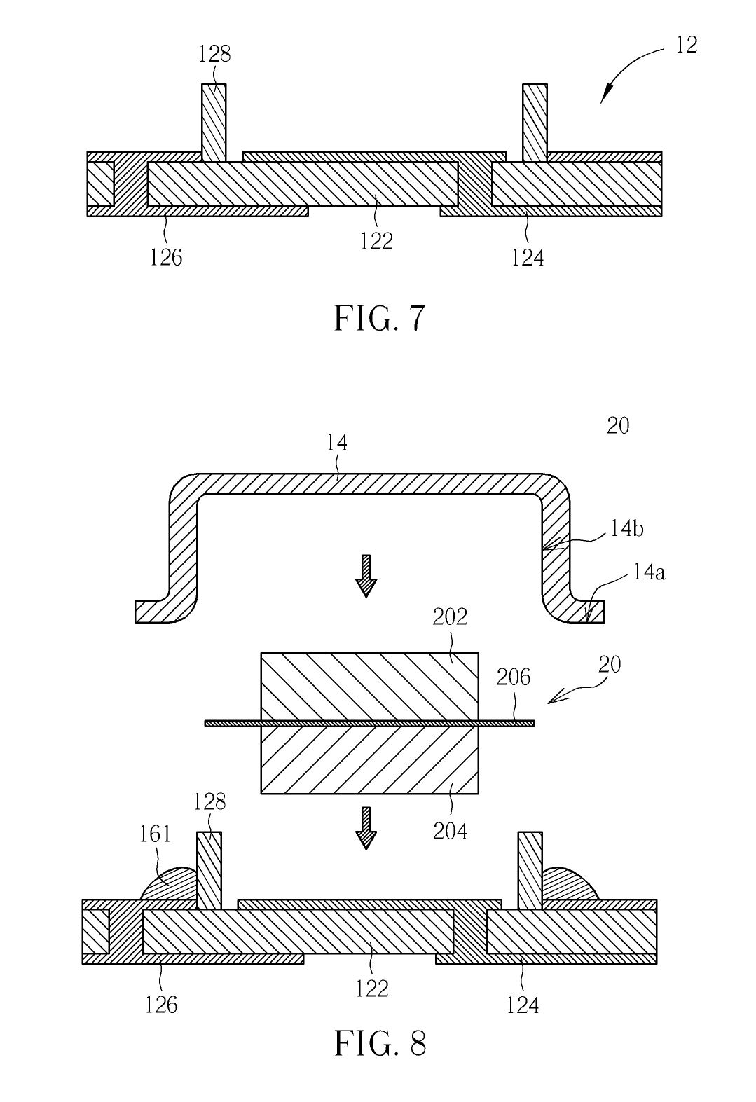

Please refer to FIG. 6, which is a flow chart of a method of manufacturing an energy storage device of an embodiment according to the invention. For simple illustration, the following is based on the structure of the energy storage device 1. As shown by the step S110, the method is first to prepare a circuit board 12. As shown in FIG. 7, the circuit board 12 includes an insulation substrate 122, a first electrode circuit 124 and a second electrode circuit 126 formed on the insulation substrate 122, and an insulation protrusion ring 128 on the insulation substrate 122. In practice, the method is able to obtain the insulation substrate 122 first and then to form the first electrode circuit 124 and the second electrode circuit 126 on the insulation substrate 122. Alternatively, the method is able to form the insulation substrate 122, the first electrode circuit 124, and the second electrode circuit 126 together, for example by a co-fired ceramics process or directly by a common PCB. The insulation protrusion ring 128 is additionally disposed on the insulation substrate 122. For example, a laminated structure of dry films is formed on the insulation substrate 122 by a dry film process, so as to be regarded as the insulation protrusion ring 128. Furthermore, in practice, the insulation substrate 122 can be formed together with the insulation protrusion ring 128 by a one-piece production way, such as a process for low-temperature co-fired ceramics or high-temperature co-fired ceramics or an injection process of synthetic resin, but the invention is not limited thereto.

Please also refer to FIG. 8. As shown by the step S120 in FIG. 6, the method is to prepare a conductive cover 14 having a circumference 14a. The conductive cover 14 is provided in a cup structure. The circumference 14a is located at the cup rim of the cup structure. As shown by the step S130, the method is then to dispose cell contents including an upper electrode 202, a lower electrode 204, a separator 206, and electrolyte infiltrating in the upper electrode 202 and the lower electrode 204. In practice, the disposition of the cell contents can be implemented on both the conductive cover 14 and the circuit board 12 (at the inner side of the insulation protrusion ring 128), or the cell contents can be assembled in advance to form an electrochemical cell 20 which is then disposed on the conductive cover 14 or on the circuit board 12 (at the inner side of the insulation protrusion ring 128); however, the invention is not limited thereto. For simple illustration, FIG. 8 only illustrates the relative positions of the conductive cover 14, the electrochemical cell 20, and the circuit board 12, which is not only applicable to the case of the cell contents being assembled in advance.

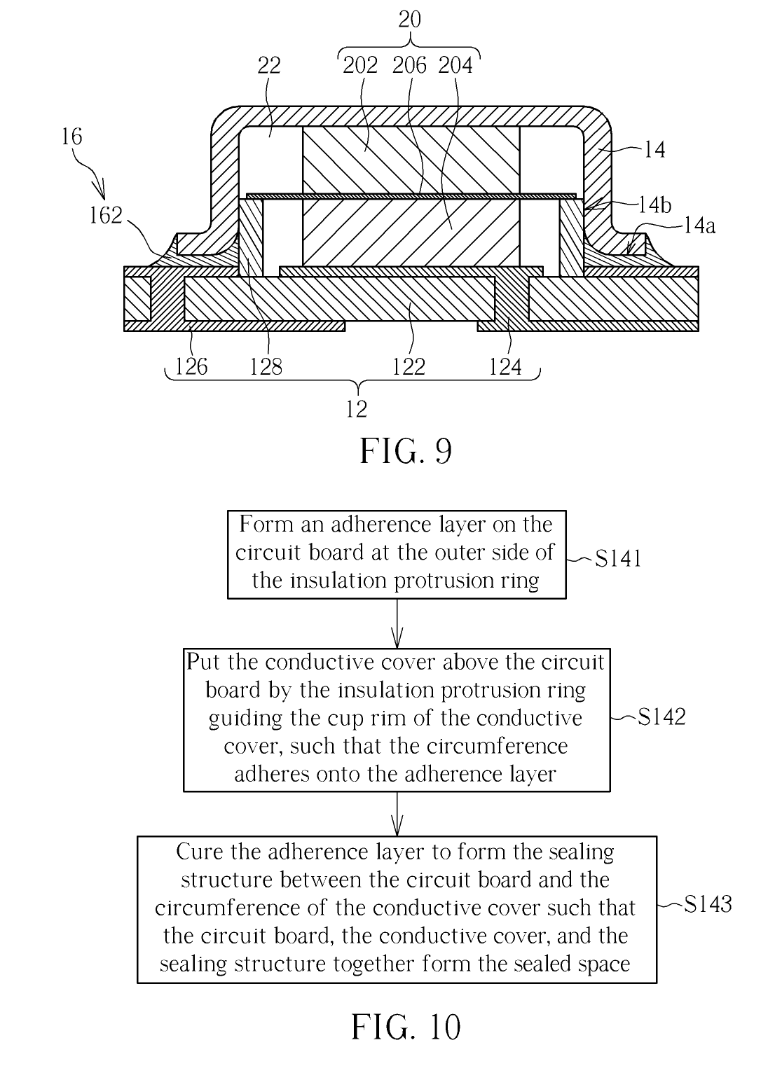

Please also refer to FIG. 8 and FIG. 9. As shown by the step S140 in FIG. 6, the method is to implement a sealing process to put and fix the conductive cover 14 above the circuit board 12 and to form a sealing structure 16 between the circuit board 12 and the circumference 14a of the conductive cover 14 such that the circuit board 12, the conductive cover 14, and the sealing structure 16 together form a sealed space 22 where the insulation protrusion ring 128 is disposed. The electrochemical cell 20 is disposed at the inner side of the insulation protrusion ring 128 and electrically connected to the first electrode circuit 124 and the second electrode circuit 126 respectively. In the embodiment, the step S140 is implemented by the following steps in practice. As shown by the step S141 in FIG. 10, the method is to form an adherence layer 161 on the circuit board 12 at the outer side of the insulation protrusion ring 128. As shown by the step S142, the method is to put the conductive cover 14 above the circuit board 12 by the insulation protrusion ring 128 guiding the cup rim of the conductive cover 14, such that the circumference 14a adheres onto the adherence layer 161. As shown by the step S143, the method is then to cure the adherence layer 161 to form the sealing structure 16 between the circuit board 12 and the circumference 14a of the conductive cover 14 such that the circuit board 12, the conductive cover 14, and the sealing structure 16 together form the sealed space 22. Therein, the electrochemical cell 20 is disposed in the sealed space 22 and electrically connected to the first electrode circuit 124 and the second electrode circuit 126 respectively. In the embodiment, the sealing structure 16 is provided in a ring structure and includes a welding metal portion 162. The adherence layer 161 consists mainly of metal solder. The welding metal portion 162 is therefore formed by heating the adherence layer 161 to a welding temperature. The welding temperature is lower than a reflow temperature for the energy storage device 1. For the choice for the adherence layer 161, please refer to the relative description of the welding metal portion 162 of the abovementioned energy storage device 1, which is not described herein.

Afterward, as shown by the step S150 in FIG. 6, the method is to form a metal coating layer 18 successively covering the conductive cover 14, the exposed portion of the sealing structure 16, and the circuit board 12. In the embodiment, the metal coating layer 18 covers the whole conductive cover 14, the exposed portion of the sealing structure 16, and a portion of the circuit board 12. In addition, in practice, the metal coating layer 18 can be formed by a physical, chemical or electrochemical coating method, but the invention is not limited thereto. For other description of the metal coating layer 18, please refer to the relative description of the metal coating layer 18 of the abovementioned energy storage device 1, which is not described herein.

So far the energy storage device 1 is substantially completed. It is added that in practice, the metal coating layer 18 can proceed to a heat treatment further, so as to improve the crystallization for enhancing the strength thereof. It is added further that if the adherence layer 161 includes a metal solder and a macromolecule adhesive, the macromolecule adhesive can be cured to from the adhesive portion 164 in advance, or can be cured together with the curing of the metal solder, so as to form the sealing structure 16 including the welding metal portion 162 and the adhesive portion 164, as shown in FIG. 2.

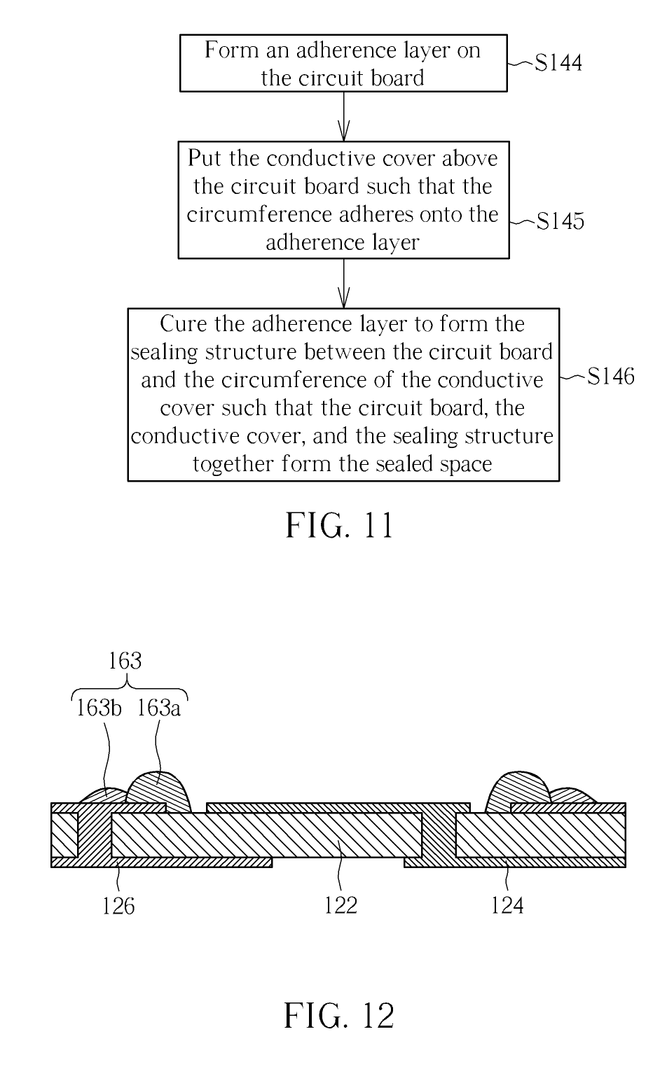

Please also refer to FIG. 3. The manufacturing of the energy storage device 4 is substantially equal to the manufacturing of the energy storage device 1. In the embodiment, because the energy storage device 4 is provided without the insulation protrusion ring 128, the step S140 is implemented by the following steps in practice. As shown by the step S144 in FIG. 11, the method is form an adherence layer 163 on the circuit board 12 to surround the lower electrode 204. As shown by the step S145, the method is to put the conductive cover 14 above the circuit board 12 such that the circumference 14a adheres onto the adherence layer 163. As shown by the step S146, the method is then to cure the adherence layer 163 to form the sealing structure 16 between the circuit board 12 and the circumference 14a of the conductive cover 14 such that the circuit board 12, the conductive cover 14, and the sealing structure 16 together form the sealed space 22. Therein, the electrochemical cell 20 is disposed in the sealed space 22 and electrically connected to the first electrode circuit 124 and the second electrode circuit 126 respectively. In the embodiment, please refer to FIG. 8 for illustration of the above steps; schematic diagrams for illustrating the above steps will not drawn additionally. In the embodiment, the sealing structure 16 includes the welding metal portion 162 and the adhesive portion 164. The welding metal portion 162 and the adhesive portion 164 respectively are disposed in circle. The adhesive portion 164 is located at the inner side of the welding metal portion 162. The adhesive portion 164 is disposed between the circuit board 12 and the cup rim of the conductive cover 14 and extends upward along the inner sidewall 14b of the conductive cover 14 for electrically separating the lower electrode 204 and the conductive cover 14. In practice, the adherence layer 163 includes a macromolecule adhesive 163a and a metal solder 163b. The macromolecule adhesive 163a and the metal solder 163b respectively spread in circle. The macromolecule adhesive 163a is disposed at the inner side of the metal solder 163b, as shown in FIG. 12. The macromolecule adhesive 163a can be cured to form the adhesive portion 164 by heating the adherence layer 163 to about 100 degrees Celsius, but the invention is not limited thereto. The practical heating temperature depends on the curing condition of the macromolecule adhesive 163a. The solidification by heating of the metal solder 163b can be understood by referring to the relative description of the welding metal portion 162 in the foregoing paragraphs. For the choice for the adherence layer 163 and other description of the sealing structure 16, please refer to the relative description of the sealing structure 16 of the energy storage device 4, which is not described herein.

In the structure shown in FIG. 4, the conductive cover 14 includes the insulation coating layer 142 on the inner sidewall 14b thereof close to the cup rim (or the circumference 14a). It is unnecessary for the adhesive portion 164 to be the insulation structure between the lower electrode 204 and the conductive cover 14, so the energy storage device 5 shown in FIG. 4 can be manufactured by the same process for the energy storage device 4; therein, the size control of the adhesive portion 164 of the energy storage device 5 can be realized by controlling the spreading of the macromolecule adhesive 163a in the step S144.

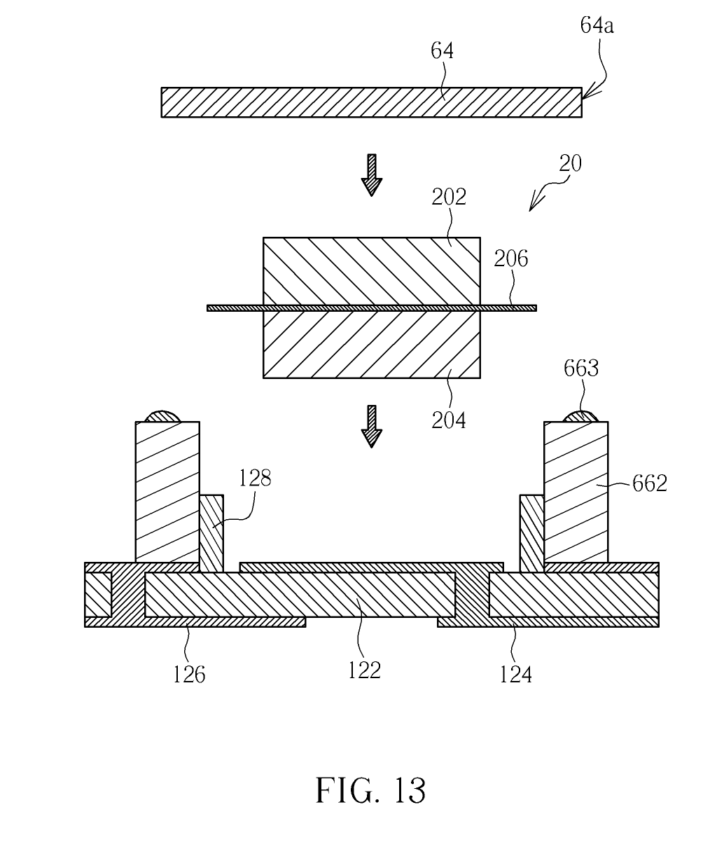

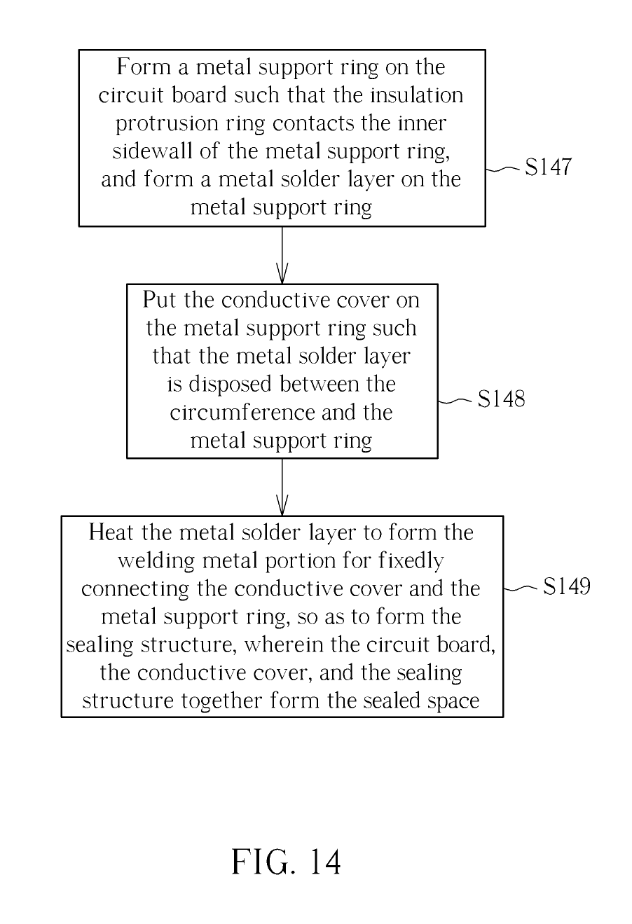

Please also refer to FIG. 5 and FIG. 13. The conductive cover 64 of the energy storage device 6 is provided in a plate structure, but the invention is not limited thereto. The sealing structure 66 includes the metal support ring 662 and the welding metal portion 664, so in the embodiment, the step S140 in FIG. 6 is implemented by the following steps in practice. As shown by the step S147 in FIG. 14, the method is to form a metal support ring 662 on the circuit board 12 such that the insulation protrusion ring 128 contacts the inner sidewall of the metal support ring 662, and to form a metal solder layer 663 on the metal support ring 662. As shown by the step S148, the method is to put the conductive cover 64 on the metal support ring 662 such that the metal solder layer 663 is disposed between the circumference 64a and the metal support ring 662. As shown by the step S149, the method is to heat the metal solder layer 663 to form the welding metal portion 664 for fixedly connecting the conductive cover 64 and the metal support ring 662; therein, the metal support ring 662 and the welding metal portion 664 form the sealing structure 66 such that the circuit board 12, the conductive cover 64, and the sealing structure 66 together form the sealed space 22. The electrochemical cell 20 is disposed in the sealed space 22 and electrically connected to the first electrode circuit 124 and the second electrode circuit 126 respectively. For the choice for metal solder layer 663 and other description of the sealing structure 66, please refer to the relative description of the sealing structure 66 of the abovementioned energy storage device 6, which is not described herein.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An energy storage device, comprising:
a circuit board comprising an insulation substrate and a first electrode circuit and a second electrode circuit formed on the insulation substrate;
a conductive cover having a circumference;
a sealing structure disposed between the circuit board and the circumference of the conductive cover such that the circuit board, the conductive cover, and the sealing structure together form a sealed space;
a metal coating layer successively covering a portion of the conductive cover, an exposed portion of the sealing structure, and a portion of the circuit board; and
an electrochemical cell disposed in the sealed space and electrically connected to the first electrode circuit and the second electrode circuit respectively.

2. The energy storage device of claim 1, wherein the sealing structure comprises a welding metal portion and is provided in a ring structure, and a welding temperature of the welding metal portion is lower than a reflow temperature for the energy storage device.

3. The energy storage device of claim 2, wherein the sealing structure further comprises an adhesive portion, the welding metal portion and the adhesive portion respectively are disposed in circle, and the adhesive portion is at an inner side of the welding metal portion.

4. The energy storage device of claim 2, wherein the welding metal portion is of an alloy of Sn—Ag—Cu, and the metal coating layer is of Cu.

5. The energy storage device of claim 1, wherein the circuit board comprises an insulation protrusion ring disposed on the insulation substrate and in the sealed space, and the electrochemical cell is disposed at an inner side of the insulation protrusion ring.

6. The energy storage device of claim 5, wherein the insulation substrate and the insulation protrusion ring are formed in one piece.

7. The energy storage device of claim 6, wherein the insulation substrate and the insulation protrusion ring are made of low-temperature co-fired ceramics, high-temperature co-fired ceramics, or synthetic resin.

8. The energy storage device of claim 5, wherein the insulation protrusion ring is a laminated structure of dry films.

9. The energy storage device of claim 5, wherein the sealing structure comprises a metal support ring and a welding metal portion, the metal support ring is fixedly disposed on the circuit board, the insulation protrusion ring contacts an inner sidewall of the metal support ring, the conductive cover is disposed on the metal support ring, and the welding metal portion seals the conductive cover and the metal support ring.

10. The energy storage device of claim 1, wherein the conductive cover is provided in a cup structure, the circumference is located at a cup rim of the cup structure, the conductive cover is connected by the cup rim to the circuit board through the sealing structure, and the conductive cover comprises an insulation coating layer on an inner sidewall of the cup structure close to the cup rim.

11. The energy storage device of claim 1, wherein the conductive cover is provided in a cup structure, the circumference is located at a cup rim of the cup structure, the conductive cover is connected by the cup rim to the circuit board through the sealing structure, the circuit board comprises an insulation protrusion ring disposed on the insulation substrate and in the sealed space, the electrochemical cell is disposed at an inner side of the insulation protrusion ring, and the insulation protrusion ring contacts an inner sidewall of the cup structure.

12. The energy storage device of claim 1, wherein the metal coating layer covers the conductive cover and the exposed portion of the sealing structure completely.

13. A method of manufacturing an energy storage device, the method comprising the following steps:
(a) preparing a circuit board, the circuit board comprising an insulation substrate and a first electrode circuit and a second electrode circuit formed on the insulation substrate;
(b) preparing a conductive cover having a circumference;
(c) disposing cell contents;
(d) implementing a sealing process to put and fix the conductive cover above the circuit board and to form a sealing structure between the circuit board and the circumference of the conductive cover such that the circuit board, the conductive cover, and the sealing structure together form a sealed space, and the cell contents form an electrochemical cell in the sealed space, wherein the electrochemical cell is electrically connected to the first electrode circuit and the second electrode circuit respectively; and
(e) forming a metal coating layer successively covering a portion of the conductive cover, an exposed portion of the sealing structure, and a portion of the circuit board.

14. The method of claim 13, wherein in the step (a), the circuit board comprises an insulation protrusion ring disposed on the insulation substrate, in the step (c), the cell contents are disposed at an inner side of the insulation protrusion ring, and in the step (d), the insulation protrusion ring is disposed in the sealed space.

15. The method of claim 14, wherein the step (a) comprises implementing a dry film process to form a laminated structure of dry films on the insulation substrate as the insulation protrusion ring.

16. The method of claim 14, wherein the step (a) comprises forming the insulation substrate and the insulation protrusion ring by a one-piece production way.

17. The method of claim 13, wherein in the step (a), the circuit board comprises an insulation protrusion ring disposed on the insulation substrate, in the step (b), the conductive cover is provided in a cup structure, in the step (c), the cell contents are disposed at an inner side of the insulation protrusion ring, and the step (d) is implemented by the following steps:
forming an adherence layer at an outer side of the insulation protrusion ring on the circuit board;
putting the conductive cover above the circuit board such that the circumference of the conductive cover adheres onto the adherence layer; and
curing the adherence layer to form the sealing structure between the circuit board and the circumference of the conductive cover.

18. The method of claim 17, wherein in the step (d), the sealing structure is provided in a ring structure and comprises a welding metal portion formed by heating the adherence layer to a welding temperature, and the welding temperature is lower than a reflow temperature for the energy storage device.

19. The method of claim 17, wherein in the step (d), the sealing structure is provided in a ring structure and comprises a welding metal portion and an adhesive portion, the welding metal portion and the adhesive portion respectively are disposed in circle, and the adhesive portion is at an inner side of the welding metal portion.

20. The method of claim 13, wherein in the step (a), the circuit board comprises an insulation protrusion ring disposed on the insulation substrate, in the step (c), the cell contents are disposed at an inner side of the insulation protrusion ring, and the step (d) is implemented by the following steps:
forming a metal support ring on the circuit board such that the insulation protrusion ring contacts an inner sidewall of the metal support ring;
forming a metal solder layer on the metal support ring;
putting the conductive cover on the metal support ring such that the metal solder layer is disposed between the circumference and the metal support ring, and the cell contents form the electrochemical cell; and
heating the metal solder layer to form a welding metal portion for fixedly connecting the conductive cover and the metal support ring, wherein the metal support ring and the welding metal portion form the sealing structure.
